(19) United States
(12) Patent Application Publication
(10) Pub. No.: US 2021/0305493 A1
(43) Pub. Date: Sep. 30, 2021

(54) METHOD OF MANUFACTURING DIELECTRIC FILM

(71) Applicant: MITSUBISHI HEAVY INDUSTRIES, LTD., Tokyo (JP)

(72) Inventors: Yasuhiko TSURU, Tokyo (JP); Yuko YAMAMOTO, Tokyo (JP); Takashi NAKANO, Tokyo (JP); Kentaro JINNO, Tokyo (JP); Misaki FUKUYAMA, Tokyo (JP); Yuki ASAI, Tokyo (JP)

(21) Appl. No.: 17/146,841

(22) Filed: Jan. 12, 2021

(30) Foreign Application Priority Data
Mar. 31, 2020 (JP) 2020-061815

(51) Int. Cl. H01L 41/314; G01B 17/02; H01L 41/08

(52) U.S. Cl. CPC H01L 41/314; H01L 41/0805; G01B 17/02

(57) ABSTRACT

A method of manufacturing a dielectric film includes the steps of: adjusting a particle size distribution of particles of a dielectric substance to fall within a specified range; kneading the particles having the adjusted particle size distribution and a dispersion medium to obtain a slurry; and forming the slurry into a film shape to obtain a film-like compact.

### CROSS-REFERENCE TO RELATED APPLICATIONS

This application claims the benefit of priority to Japanese Patent Application Number 2020-061815 filed on Mar. 31, 2021. The entire contents of the above-identified application are hereby incorporated by reference.

### TECHNICAL FIELD

The present disclosure relates to a method of manufacturing a dielectric film.

### RELATED ART

As a piezoelectric body of an ultrasonic sensor such as a thickness sensor, a dielectric film (such as a piezoelectric ceramic film) subjected to polarization processing may be used.

For example, in an ultrasonic thickness sensor disclosed in Japanese Patent Application Laid-Open No. 2013-140887, a thin sheet is formed from a slurry containing material powder of a ceramic piezoelectric body, the sheet is adhered to one surface of a thin metal plate serving as one electrode of the sensor, and the sheet is sintered to form a film-like sintered body, which is then subjected to polarization processing and used as the piezoelectric body. The ultrasonic thickness sensor is used in a state of being attached to a measurement object via an adhesive layer provided between the other surface (surface on which the piezoelectric body is not provided) of the thin metal plate (one electrode) and the surface of the thickness measurement object.

### SUMMARY

A thin ultrasonic sensor including a film-like piezoelectric body (dielectric film) has excellent flexibility, and thus is suitable for measuring thickness of a measurement object having a curved surface (e.g., piping). In addition, such a thin ultrasonic sensor is easily installed on a measurement object at any given time, thereby facilitating continuous measurement of the measurement object and suppressing variation in measurement accuracy over time.

On the other hand, in a conventional thin ultrasonic sensor employing a dielectric film (e.g., that disclosed in Japanese Patent Application Laid-Open No. 2013-140887), the measurement accuracy may decrease with time due to deterioration of an adhesive layer provided between the ultrasonic sensor and the surface of the measurement object.

In view of the above circumstances, an object of at least one embodiment of the present invention is to provide a method of manufacturing a dielectric film capable of suppressing a decrease in measurement accuracy of an ultrasonic sensor.

A method of manufacturing a dielectric film according to at least one embodiment of the present invention includes:
adjusting a particle size distribution of the particles of a dielectric substance to be within a specified range;
kneading the particles having the adjusted particle size distribution and a dispersion medium to obtain a slurry; and
forming the slurry into a film shape to obtain a film-like compact.

According to at least one embodiment of the disclosure, a method of manufacturing a dielectric film capable of suppressing a decrease in measurement accuracy of an ultrasonic sensor is provided.

### BRIEF DESCRIPTION OF DRAWINGS

The disclosure will be described with reference to the accompanying drawings, wherein like numbers reference like elements.

FIG. 1 is a schematic configuration diagram of an ultrasonic sensor to which a dielectric film according to an embodiment is applied.

FIG. 2 is a flow chart of a method of manufacturing a dielectric film 2 according to an embodiment.

FIG. 3A is a schematic view of a film-forming instrument used in a method of manufacturing according to an embodiment.

FIG. 3B is a schematic view of a film-forming instrument used in a method of manufacturing according to an embodiment.

FIG. 4A is a schematic view of a film-forming instrument used in a method of manufacturing according to an embodiment.

FIG. 4B is a schematic view of a film-forming instrument used in a method of manufacturing according to an embodiment.

FIG. 5A is a diagram for illustrating a procedure of a method of manufacturing according to an embodiment.

FIG. 5B is a diagram for illustrating a procedure of a method of manufacturing according to an embodiment.

FIG. 5C is a diagram for illustrating a procedure of a method of manufacturing according to an embodiment.

FIG. 6A is a diagram for illustrating a procedure of a method of manufacturing according to an embodiment.

FIG. 6B is a diagram for illustrating a procedure of a method of manufacturing according to an embodiment.

### DESCRIPTION OF EMBODIMENTS

Hereinafter, some embodiments of the present invention will be described with reference to the accompanying drawings. However, the dimensions, materials, shapes, relative arrangements, and other characteristics of the components described in the embodiments or illustrated in the drawings are not intended to limit the scope of the present invention and are merely explanatory examples.

### Configuration Example of Ultrasonic Sensor

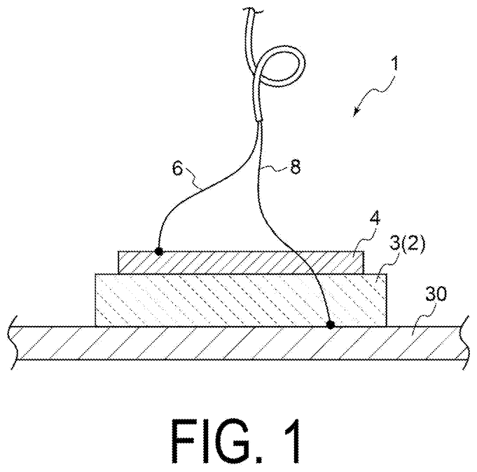

First, as an application example of a dielectric film manufactured by a method of manufacturing according to some embodiments, an ultrasonic sensor to which a dielectric film according to an embodiment is applied will be described. FIG. 1 is a schematic configuration diagram of an ultrasonic sensor to which a dielectric film according to an embodiment is applied. In the present specification, a piezoelectric body is a concept including a dielectric body, and a dielectric body (film) that exhibits piezoelectricity by being subjected to polarization processing is referred to as a piezoelectric body (film).

An ultrasonic sensor 1 illustrated in FIG. 1 is an ultrasonic sensor used for inspecting an inspection object 30, and includes a dielectric film 2 (a piezoelectric film 3), an electrode 4, and lead wires 6, 8. In the example described below, the ultrasonic sensor 1 is a thickness measurement sensor configured to measure the thickness (wall thickness) of the inspection object 30 (e.g., piping).

The piezoelectric film 3 of the ultrasonic sensor 1 illustrated in FIG. 1 is provided on the surface of the inspection object 30, and the electrode 4 having a thin plate shape is provided on the surface of the piezoelectric film 3. That is, the piezoelectric film 3 is positioned between the inspection object 30 and the electrode 4, the inspection object 30 is in contact with one surface of the piezoelectric film 3, and the electrode 4 is in contact with the other surface of the piezoelectric film 3. Of the pair of lead wires 6, 8, the lead wire 6 is connected to the electrode 4, and the lead wire 8 is connected to the inspection object 30. That is, the inspection object 30 functions as an electrode paired with the electrode 4. In the ultrasonic sensor 1 configured as described above, an electric signal is applied to the piezoelectric film 3 via the pair of electrodes (the electrode 4 and the inspection object 30) to drive the piezoelectric film 3 and generate an ultrasonic wave, and the inspection object 30 is irradiated with this ultrasonic wave.

In some embodiments, the ultrasonic sensor 1 may employ an electrode different from the inspection object 30 as the electrode to be paired with the electrode 4. That is, the piezoelectric film 3 may be provided on one surface of one of the pair of electrodes. In this case, as in the case of Japanese Patent Application Laid-Open No. 2013-140887, the ultrasonic sensor 1 is used by being bonded to the inspection object 30 via an adhesive layer provided between one of the pair of electrodes and the inspection object 30. The adhesive layer may be formed of, for example, a silver paste or a glass paste.

### Method of Manufacturing Dielectric Film

Hereinafter, a method of manufacturing the dielectric film 2 according to some embodiments will be described.

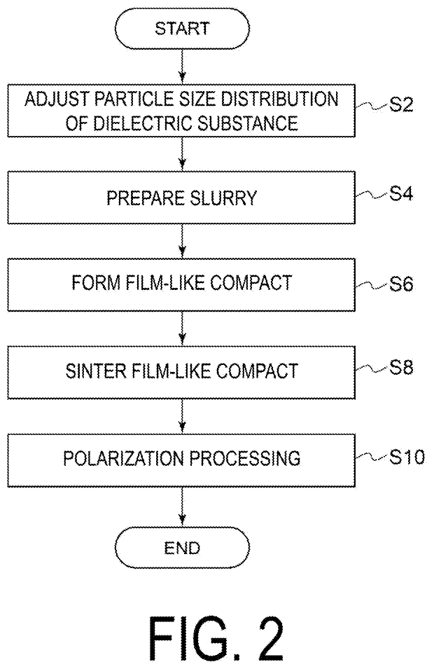

FIG. 2 is a flowchart of a method of manufacturing the dielectric film 2 according to an embodiment. As illustrated in FIG. 2, a method of manufacturing the dielectric film 2 according to an embodiment includes the steps of: adjusting the particle size distribution of particles of a dielectric substance (step S2); preparing a slurry containing the particles obtained in step S2 (step S4); forming the slurry to obtain a film-like compact (dielectric film 2) (step S6); sintering the film-like compact (dielectric film 2) (step S8); and subjecting the sintered film-like compact (dielectric film 2) to polarization processing (step S10).

### Adjustment of Particle Size Distribution of Particles of Dielectric Substance; Step S2

In step S2, the particle size distribution of the particles of the dielectric substance is adjusted to fall within a specified range.

As described above, by adjusting the particle size distribution of the particles of the dielectric substance to fall within the specified range, even when the film-like compact formed from the slurry containing the particles of the dielectric substance is sintered while being provided on the surface of the inspection object 30 in a subsequent step, the dielectric substance can be provided with an appropriate particle size distribution such that the film-like compact after sintering does not easily peel off from the surface of the inspection object 30. Therefore, the sintered product of the film-like compact can be directly formed on the surface of the inspection object without using an adhesive or the like. The film-like compact is not necessarily formed on the surface of the inspection object and may be formed on the surface of a thin plate-shaped electrode.

In one embodiment, in step S2, the particle size distribution of the particles of the dielectric substance is adjusted such that D50 falls within the range of from 0.5 μm to 0.7 μm. Alternatively, in step S2, the particle size distribution of the particles of the dielectric substance may be adjusted such that D50 falls within the range of from 0.55 μm to 0.65 μm. By using the particles having a particle size distribution adjusted to fall within the above-described range, even when the film-like compact formed from the slurry containing the particles of the dielectric substance is sintered while being provided on the surface of the inspection object 30, the film-like compact after sintering less easily peels off from the surface of the inspection object. Therefore, the sintered product of the film-like compact (film-like sintered body) is more easily directly formed on the surface of the inspection object without using an adhesive or the like.

In the present specification, D50 means a particle diameter at an integrated value of 50% in a particle size distribution obtained by a laser diffraction/scattering method.

The type of dielectric substance is not particularly limited and, for example, particles of PZT (lead zirconate titanate) can be used. As the particles of the dielectric substance such as PZT, commercially available particles can be used.

In one embodiment, in step S2, the particles of the dielectric substance (e.g., PZT) may be calcined to at least partially fuse the particles together to adjust the particle size distribution of the particles.

The temperature at which the particles of the dielectric substance are calcined may be from 800° C. to 1000° C. The time for calcining the particles of the dielectric substance may be from 2 hours to 5 hours.

By calcining the particles of the dielectric substance, even when the film-like compact formed from the slurry containing the calcined particles is sintered while being provided on the surface of the inspection object, the dielectric substance (calcined particles) can be provided with an appropriate particle size distribution such that the film-like compact after sintering does not easily peel off from the surface of the inspection object. In addition, by performing calcination in the above-described temperature range, the dielectric substance (calcined particles) can more easily be imparted with an appropriate particle size distribution as described above.

### Preparation of Slurry; Step S4

In step S4, the particles of the dielectric substance obtained in step S2 (i.e., the particles having the adjusted particle size distribution) and a dispersion medium are kneaded to obtain a slurry. The preparation of the slurry in step S4 may be performed by, for example, adding a dispersion medium to the above-described particles and kneading the mixture using a roll mill, a ball mill, or the like. Further, a rotary evaporator or the like may be used to remove the solvent (remove the solvent by volatilization) simultaneously with a defoaming treatment to obtain a slurry having a predetermined viscosity. The viscosity of the slurry obtained in step S4 may be a viscosity suitable for film formation in the following step of obtaining a film-like compact. The viscosity of the slurry generated in step S4 may be, for example, from 1500 mPa·s to 20000 mPa·s.

In some embodiments, the dispersion medium used to prepare the slurry is a solution of a resin dissolved in an organic solvent.

The above resin may contain a substance capable of appropriately adjusting the viscosity of the dispersion medium. This makes it easy to appropriately adjust the viscosity of the obtained slurry. As the resin, for example, polyvinyl butyral (PVB) or the like can be used.

The organic solvent may contain a substance that has a relatively low vapor pressure and is difficult to evaporate (e.g., a substance having a vapor pressure lower than that of ethanol). Accordingly, the viscosity of the prepared slurry is less likely to change with time, meaning that the film-like compact is more easily formed in the following step. As the organic solvent, an alcohol such as butanol can be used.

The concentration of the solution in which the resin is dissolved in the organic solvent may be, for example, from 10 wt. % to 20 wt. %.

In some embodiments, the dispersion medium used to prepare the slurry does not include a sol component as a binder. That is, the dispersion medium used to prepare the slurry (the dispersion medium kneaded with the particles of the dielectric substance) does not include a dispersoid constituting the sol as the binder. Such a dispersoid is, for example, a metal salt such as a metal alkoxide or a metal carboxylate having a function as a binder. The metal atoms constituting the metal salt may be of the same type as the metal atoms constituting the dielectric substance. That is, when the dielectric substance is PTZ, the metal atoms constituting the metal salt may include titanium, zirconium, or lead. More specifically, when the dielectric substance is PTZ, the metal salt may be titanium butoxide, zirconium butoxide, and lead acetate.

Usually, when the slurry is prepared, a dispersion medium containing a sol component having a binder function is used. In a case where the dispersion medium contains the above-described sol component, a binder function is exhibited by a dehydration condensation reaction between the sol components at the time of sintering the film-like compact formed from the slurry.

On the other hand, in the above-described embodiment, as described above, since particles of a dielectric substance having an appropriate particle size distribution are used, even when the slurry is prepared by using a dispersion medium that does not contain the sol component as the binder, the film-like compact that does not easily peel off from the surface of the inspection object after sintering can be formed. Therefore, it is possible to more easily manufacture the dielectric film capable of suppressing a decrease in measurement accuracy of the ultrasonic sensor.

### Formation of Film-like Compact; Step S6

In step S6, the slurry prepared in step S4 is formed to obtain a film-like compact (dielectric film 2). When forming the film-like compact used for the ultrasonic sensor, the thickness of the film-like compact formed in step S6 may be from 60 μm to 80 μm. By setting the film thickness of the film-like compact to 60 μm or more, the detection accuracy of the ultrasonic sensor using the film-like compact can be improved. In addition, setting the film thickness of the film-like compact to 80 μm or less affords the film-like compact with appropriate flexibility and, for example, the ultrasonic sensor can be appropriately installed on the inspection object having a curved surface.

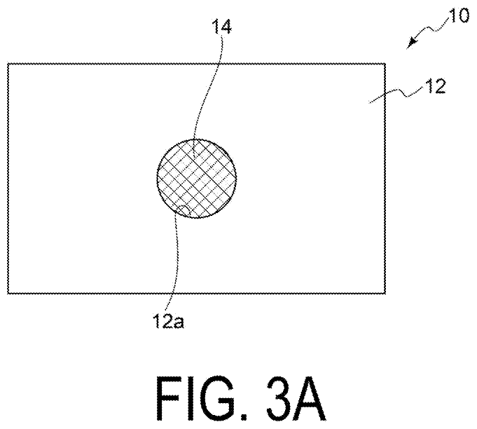

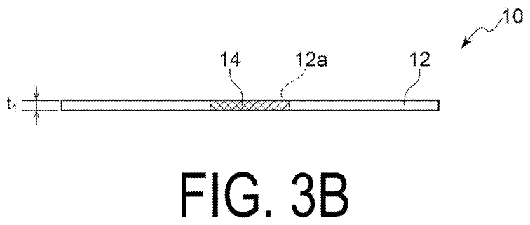

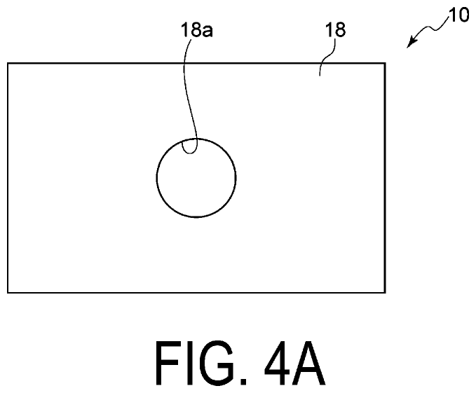

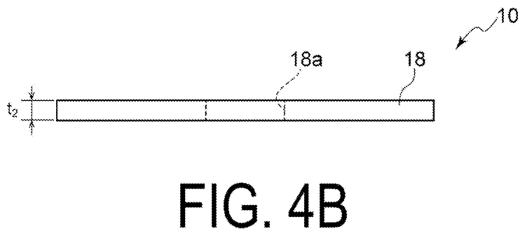

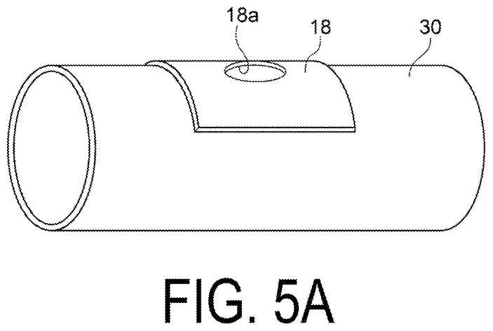

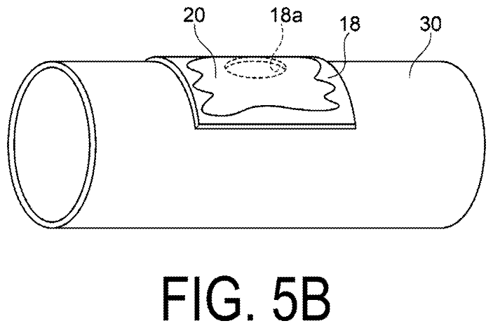

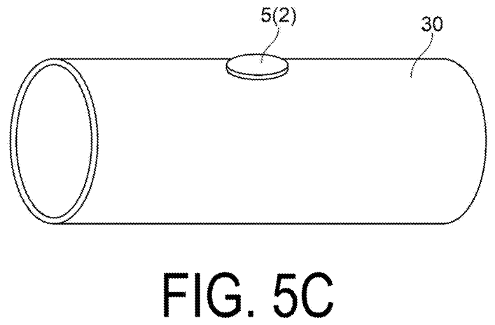

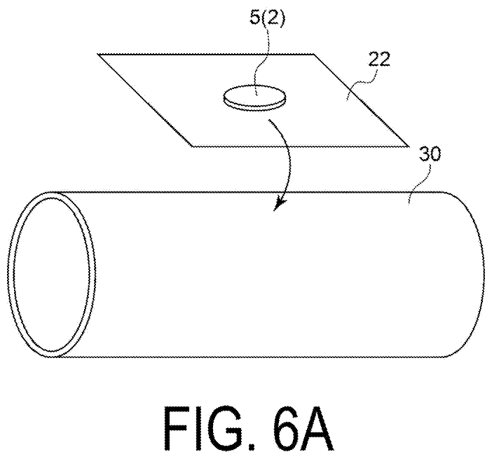

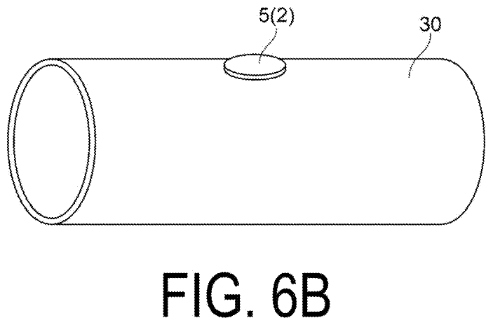

Here, FIGS. 3A and 3B, and FIGS. 4A and 4B are schematic views of a film-forming instrument 10 used for forming a film-like compact in the method of manufacturing according to an embodiment. FIGS. 3A and 4A are schematic plan views of the film-forming instrument 10, and FIGS. 3B and 4B are side views of the film-forming instrument 10. FIGS. 5A to 5C and FIGS. 6A and 6B are diagrams for illustrating a procedure of forming a film-like compact in the method of manufacturing according to an embodiment.

In some embodiments, a film-like compact (dielectric film 2) may be obtained by forming the slurry into a film shape by using a screen printing method. In this case, the slurry may be formed into a film shape by using, for example, the film-forming instrument 10 illustrated in FIGS. 4A and 4B.

The film-forming instrument 10 illustrated in FIGS. 3A and 3B includes a thin plate-shaped screen sheet 12 and a mesh portion 14 provided inside a hole 12a formed in the screen sheet 12. The screen sheet 12 has a relatively small thickness t1, which is suitable for manufacturing a dense film.

When a film-like compact is formed by using the film-forming instrument 10, the screen sheet 12 is placed on the surface of an object (e.g., an inspection object) on which the film-like compact is to be formed, and an appropriate amount of the slurry prepared in step S4 is poured from above the screen sheet 12 to fill the gaps of the mesh portion 14 with the slurry. Then, the screen sheet 12 is removed from the surface of the object. This process forms a thin film of slurry on the surface of the object. After the film is dried, another thin film is formed on the film by the same procedure using the film-forming instrument 10. A film-like compact can be obtained by repeating this procedure until the slurry film has a desired thickness.

By forming the slurry into a film shape by using a screen printing method as described above, a film-like compact can be obtained relatively easily. In addition, by forming the slurry into a film shape by using a screen printing method, the shape and thickness of the film can be finely adjusted easily, such that a film-like compact having good dimensional accuracy or good shape accuracy can be obtained.

In some embodiments, the film-like compact (dielectric film 2) may be obtained by forming the slurry into a film shape by using a stencil printing method. In this case, the slurry may be formed into a film shape by using, for example, the film-forming instrument 10 illustrated in FIGS. 5A and 5B.

The film-forming instrument 10 illustrated in FIGS. 4A and 4B includes a thin plate-shaped template 18 provided with a hole 18a. The template has a relatively thick thickness t2, and a relatively thick film of slurry can be formed by a single operation. Thus, the template is suitable for simple film production.

When a film-like compact is formed by using the film-forming instrument 10, the template 18 is placed on the surface of an object (e.g., an inspection object) on which the film-like compact is to be formed (see FIG. 5A), an appropriate amount of a slurry 20 prepared in step S4 is poured from above the template 18 (see FIG. 5B) to fill the inside of the hole 18a with the slurry 20, and then the template 18 is removed from the surface of the object (see FIG. 5C).

This forms a film of slurry on the surface of the object. Thus, a film-like compact 5 (dielectric film 2) can be obtained.

By forming the slurry into a film shape by using a stencil printing method as described above, a film-like compact can be obtained relatively easily. In addition, by forming the slurry into a film shape by using a stencil printing method, a film-like compact having a relatively large thickness can be obtained with a relatively small number of operations, which is simpler.

In one embodiment, as illustrated in FIGS. 5A to 5C, for example, in step S6, the film-like compact (dielectric film 2) is directly formed on the surface of the inspection object 30 (e.g., piping). In this case, in the following steps, the film-like compact (dielectric film 2) on the surface of the inspection object 30 is sintered (step S8), and then the sintered product (dielectric film 2) of the film-like compact on the surface of the inspection object 30 is subjected to polarization treatment (step S10) to obtain the piezoelectric film 3 (dielectric film 2).

In one embodiment, as illustrated in FIG. 6A, for example, in step S6, the film-like compact 5 (dielectric film 2) is formed on a release sheet 22. Then, as illustrated in FIG. 6B, the film-like compact 5 that has been peeled off from the release sheet 22 is bonded to the surface of the inspection object 30 by using the ultrasonic sensor. Then, in the following steps, the film-like compact (dielectric film 2) on the surface of the inspection object 30 is sintered (step S8), and then the sintered product (dielectric film 2) of the film-like compact on the surface of the inspection object 30 is subjected to polarization treatment (step S10) to obtain the piezoelectric film 3 (dielectric film 2).

The release sheet 22 is a sheet that can be easily peeled off after the film-like compact 5 is formed. For example, the release sheet 22 may be provided with a water-soluble adhesive layer made of cellulose or the like. When the film-like compact 5 is formed on the surface of the adhesive layer of the release sheet 22, the film-like compact 5 can be easily peeled off from the release sheet 22 by immersing the release sheet 22 in water, and the film-like compact 5 that has been peeled off from the release sheet 22 can be easily attached to the surface of the inspection object 30. Therefore, the step of forming the film-like compact 5 on the release sheet 22 can be performed in a factory, for example, and the step of attaching the film-like compact 5 to the surface of the inspection object 30 can be performed in a plant, for example, meaning that these steps can be performed in different places. Thus, work at the installation location of the inspection object 30 can be made simpler.

In one embodiment, although not illustrated, in step S6, the film-like compact (dielectric film 2) may be formed on a thin plate-shaped electrode. An ultrasonic sensor including such a film-like compact (dielectric film 2) is bonded to the inspection object 30 by using an adhesive layer provided between the electrode and the inspection object 30, as in the case of Japanese Patent Application Laid-Open No. 2013-140887. Then, the film-like compact (dielectric film 2) on the electrode is sintered (step S8), and then polarization processing is performed (step S10) on the sintered product (dielectric film 2) of the film-like compact on the electrode to obtain the piezoelectric film 3 (dielectric film 2).

### Sintering of Film-like Compact; Step S8

In step S8, the film-like compact formed in step S6 is sintered. In step S8, for example, the film-like compact may be sintered by locally heating only the installation location of the film-like compact in the inspection object 30 or the like by using an induction heating device or the like.

The temperature at which the film-like compact is sintered in step S8 may be, for example, from 600° C. to 700° C. In general, the temperature at which the film-like compact formed from the slurry is sintered is in a higher temperature range. However, in the present embodiment, since sintering is performed on the film-like compact formed from the calcined particles having an appropriate particle size distribution due to the calcination performed in step S2, the film-like compact can be appropriately sintered even in a relatively low temperature range.

### Polarization Processing of Film-like Compact; Step S10

In step S10, the sintered product of the film-like compact obtained in step S8 is subjected to polarization processing to obtain the piezoelectric film 3 (dielectric film 2). For example, as illustrated in FIG. 1, the polarization processing can be performed by applying a voltage between a pair of electrodes (the electrode 4 and the inspection object 30 in the example illustrated in FIG. 1) provided on both sides of the film-like compact (dielectric film 2).

The contents described in each of the above embodiments can be understood as follows, for example.

(1) A method of manufacturing a dielectric film (2) according to at least one embodiment of the present invention includes the steps of:
adjusting a particle size distribution of particles of a dielectric substance to fall within a specified range (e.g., step S2 described above);
kneading the particles having the adjusted particle size distribution and a dispersion medium to obtain a slurry (e.g., step S4 described above); and
forming the slurry into a film shape to obtain a film-like compact (e.g., step S6 described above).

In the above method (1), the particle size distribution of the particles of the dielectric substance is adjusted to fall within a specified range. By using particles whose particle size distribution is adjusted as described above, even when the film-like compact formed from the slurry containing the particles is sintered while being provided on the surface of the inspection object (30; thickness measurement object or the like), the dielectric substance can be provided with an appropriate particle size distribution such that the film-like compact after sintering does not easily peel off from the surface of the inspection object. Therefore, the sintered product of the film-like compact (film-like sintered body) can be directly formed on the surface of the inspection object without using an adhesive or the like. Therefore, according to the method of (1), it is possible to obtain a dielectric film capable of suppressing a decrease in measurement accuracy of an ultrasonic sensor (1) due to deterioration of the adhesive or the like.

(2) In some embodiments, in the above method of (1),
in the adjusting step, the particle size distribution of the particles of the dielectric substance is adjusted such that D50 falls within the range of from 0.5 μm to 0.7 μm.

According to the method of (2), since the D50 of particles of the dielectric substance is adjusted to fall within the range of from 0.5 μm to 0.7 μm, by using these particles whose particle size distribution is adjusted in this manner, even when the film-like compact formed from the slurry containing the particles of the dielectric substance is sintered while being provided on the surface of the inspection object, the film-like compact after sintering is less likely to peel off from the surface of the inspection object. Therefore, the sintered product of the film-like compact (film-like sintered body) is more easily directly formed on the surface of the inspection object without using an adhesive or the like.

(3) In some embodiments, in the method of (1) or (2), in the adjusting step, the particles of the dielectric substance are calcined to at least partially fuse the particles to each other.

According to the above method of (3), since the particles of the dielectric substance are calcined so that the particles are partially fused to each other, even when the film-like compact formed from the slurry containing the calcined particles is sintered while being provided on the surface of the inspection object, the dielectric substance (calcined particles) can be provided with an appropriate particle size distribution such that the film-like compact after sintering does not easily peel off from the surface of the inspection object.

(4) In some embodiments, in the above method of (3),
the particles are calcined at a temperature of from 800° C. to 1000° C.

According to the above method of (4), since the particles of the dielectric substance are calcined at a temperature of 800° C. to 1000° C., even when the film-like compact formed from the slurry containing the calcined particles is sintered while being provided on the surface of the inspection object, the dielectric substance (calcined particles) can be provided with an appropriate particle size distribution such that the film-like compact after sintering does not easily peel off from the surface of the inspection object. With this configuration, it is easier to obtain a dielectric film capable of suppressing a decrease in measurement accuracy of the ultrasonic sensor due to deterioration of the adhesive or the like.

(5) In some embodiments, in any one of the above methods of (1) to (4),
the method of manufacturing a dielectric film further includes
a step of sintering the film-like compact (for example, the above step S8).

According to the above method of (5), a sintered product of the film-like compact is obtained by sintering the film-like compact obtained by the method described above in (1). Therefore, a film-like piezoelectric body can be obtained by subjecting the sintered product to polarization processing. Therefore, by employing the piezoelectric body obtained in this manner in an ultrasonic sensor, as described in (1) above, a decrease in the measurement accuracy of the ultrasonic sensor can be suppressed.

(6) In some embodiments, in any one of the above methods of (1) to (5), the dispersion medium is a solution in which a resin is dissolved in an organic solvent.

According to the above method of (6), in the preparation of the slurry containing the particles of the dielectric substance, since the solution in which a resin is dissolved in an organic solvent is used as the dispersion medium, it is possible to obtain a slurry suitable for forming the film-like compact which does not easily peel off from the surface of the inspection object after sintering. With this configuration, it is easier to obtain a dielectric film capable of suppressing a decrease in measurement accuracy of the ultrasonic sensor.

(7) In some embodiments, in the above method of (6),
the resin contains polyvinyl butyral.

According to the above method of (7), since the resin containing polyvinyl butyral is used in the preparation of the slurry, it is possible to obtain a slurry having a viscosity suitable for the formation of a film-like compact.

(8) In some embodiments, in the above method of (6) or (7),
the organic solvent contains butanol.

According to the above method of (8), since butanol, which is an alcohol that is relatively difficult to evaporate, is used as the organic solvent, the viscosity of the slurry after adjustment is unlikely to change with time. Therefore, the film-like compact can be efficiently formed from the slurry.

(9) In some embodiments, in any one of the above methods of (6) to (8), the concentration of the resin in the solution is from 10 wt. % to 20 wt. %.

According to the above method of (9), since the concentration of the resin in the solution falls within the above range, it is possible to obtain a slurry having a viscosity suitable for the formation of a film-like compact.

(10) In some embodiments, in any one of the above methods of (1) to (9),
the dispersion medium does not contain a sol component as a binder.

According to the above method of (10), as described in (1) above, since the particles of the dielectric substance having an appropriate particle size distribution are used in the preparation of the slurry, even when the slurry is prepared by using the dispersion medium that does not contain the sol component as the binder, it is possible to form the film-like compact that does not easily peel off from the surface of the inspection object after sintering. Therefore, it is possible to more easily manufacture the dielectric film capable of suppressing a decrease in measurement accuracy of the ultrasonic sensor.

(11) In some embodiments, in any one of the above methods of (1) to (10),
in the forming step, the film-like compact having a film thickness of from 60 μm to 80 μm is formed.

According to the above method of (11), since the film thickness of the film-like compact is 60 μm or more, the detection accuracy of the ultrasonic sensor that uses the film-like compact can be improved. In addition, according to the above method of (11), since the film thickness of the film-like compact is set to 80 μm or less, the flexibility of the film-like compact is appropriate and, for example, it is possible to appropriately install the ultrasonic sensor on an inspection object having a curved surface.

(12) In some embodiments, in the above method according to any one of (1) to (11),
in the forming step, the slurry is formed into a film shape by using a screen printing method.

According to the above method of (12), by forming the slurry into a film shape by using the screen printing method, a film-like compact can be obtained relatively easily. In addition, by forming the slurry into a film shape by using a screen printing method, a film-like compact having good dimensional accuracy or good shape accuracy can be obtained.

(13) In some embodiments, in the above method according to any one of (1) to (11),
in the forming step, the slurry is formed into a film shape by using a stencil printing method.

According to the above method of (13), since the slurry is formed into a film shape by using the stencil printing method, a film-like compact can be obtained relatively easily.

(14) In some embodiments, in any one of the above methods of (1) to (13),
the dielectric film is a dielectric film for a piezoelectric body of an ultrasonic sensor, and
the forming step includes a step of forming the film-like compact on a surface of an inspection object to be inspected by the ultrasonic sensor and sintering the film-like compact on the surface of the inspection object.

According to the above method of (14), since the film-like compact obtained by the above method of (1) is formed on the surface of the inspection object (thickness measurement object or the like), when the film-like compact on the surface is sintered, the film-like compact after sintering does not easily peel off from the surface of the measurement object. Therefore, using the sintered product makes it possible to obtain a dielectric film capable of suppressing a decrease in measurement accuracy of an ultrasonic sensor due to deterioration of an adhesive or the like.

(15) In some embodiments, in any one of the above methods of (1) to (13),
in the forming step, the film-like compact is formed on a release sheet (22).

According to the above method of (15), since the film-like compact is formed on the release sheet, the film-like compact can be installed on the surface of the inspection object by attaching the film-like compact that has been peeled off from the release sheet to the surface of the inspection object, and the ultrasonic sensor can be manufactured from the film-shaped compact thus installed. That is, according to the above method (15), the film-like compact can be produced at a location away from the inspection object, and the film-like compact that has been peeled off from the release sheet can be easily installed on the surface of the inspection object. Therefore, work at the installation location of the inspection object can be further simplified.

(16) In some embodiments, in the above method of (15),
the dielectric film is a dielectric film for a piezoelectric body of an ultrasonic sensor, and
the method of manufacturing a dielectric film includes the steps of:
attaching the film-like compact peeled off from the release sheet to a surface of an inspection object to be inspected by the ultrasonic sensor; and
sintering the film-like compact on the inspection object.

According to the above method of (16), since the film-like compact formed on the release sheet by the above method of (15) is bonded to the surface of the inspection object (thickness measurement object or the like), when the film-like compact on the surface is sintered, the film-like compact after sintering does not easily peel off from the surface of the measurement object. Therefore, using the sintered product makes it possible to obtain a dielectric film capable of suppressing a decrease in measurement accuracy of an ultrasonic sensor due to deterioration of an adhesive or the like. Further, according to the above method of (16), since the step of forming the film-like compact on the release sheet and the step of attaching the film-like compact to the surface of the inspection object can be performed at different locations, work at the installation location of the inspection object can be made simpler.

Although embodiments of the present invention have been described above, the present invention is not limited to the above-described embodiments, and also includes modifications of the above-described embodiments as well as appropriate combinations of the embodiments.

In the present specification, an expression of relative or absolute arrangement such as “in a direction”, “along a direction”, “parallel”, “orthogonal”, “centered”, “concentric” or “coaxial” shall not be construed as indicating only the arrangement in a strict literal sense, and also includes a state where the arrangement is relatively displaced by a tolerance, or by an angle or a distance that can still achieve the same function.

For instance, an expression of an equal state such as “same”, “equal” and “uniform” shall not be construed as indicating only the state in which features are strictly equal, and also includes a state in which there is a tolerance or a difference that can still achieve the same function.

In addition, in the present specification, an expression of a shape such as a rectangular shape or a cylindrical shape shall not be construed as only a geometrically strict shape, and also includes a shape with unevenness or chamfered corners or the like within the range in which the same effect can be achieved.

In addition, in the present specification, an expression such as “comprising”, “including”, or “having” one component is not intended to be exclusive of other components.

While preferred embodiments of the invention have been described as above, it is to be understood that variations and modifications will be apparent to those skilled in the art without departing from the scope and spirit of the invention. The scope of the invention, therefore, is to be determined solely by the following claims.

1. A method of manufacturing a dielectric film, the method comprising the steps of:
adjusting a particle size distribution of particles of a dielectric substance to fall within a specified range;
kneading the particles having the adjusted particle size distribution and a dispersion medium to obtain a slurry; and
forming the slurry into a film shape to obtain a film-like compact.

2. The method of manufacturing a dielectric film according to claim 1, wherein in the adjusting step, the particle size distribution of the particles of the dielectric substance is adjusted such that D50 falls within the range of from 0.5 μm to 0.7 μm.

3. The method of manufacturing a dielectric film according to claim 1, wherein
in the adjusting step, the particles of the dielectric substance are calcined to at least partially fuse the particles to each other.

4. The method of manufacturing a dielectric film according to claim 3, wherein the particles are calcined at a temperature of from 800° C. to 1000° C.

5. The method of manufacturing a dielectric film according to claim 1, further comprising a step of sintering the film-like compact.

6. The method of manufacturing a dielectric film according to claim 1, wherein the dispersion medium is a solution in which a resin is dissolved in an organic solvent.

7. The method of manufacturing a dielectric film according to claim 6, wherein the resin contains polyvinyl butyral.

8. The method of manufacturing a dielectric film according to claim 6, wherein the organic solvent contains butanol.

9. The method of manufacturing a dielectric film according to claim 6, wherein a concentration of the resin in the solution is from 10 wt. % to 20 wt. %.

10. The method of manufacturing a dielectric film according to claim 1, wherein the dispersion medium does not contain a sol component as a binder.

11. The method of manufacturing a dielectric film according to claim 1, wherein
in the forming step, the film-like compact having a film thickness of from 60 μm to 80 μm is formed.

12. The method of manufacturing a dielectric film according to claim 1, wherein
in the forming step, the slurry is formed into a film shape by using a screen printing method.

13. The method of manufacturing a dielectric film according to claim 1, wherein
in the forming step, the slurry is formed into a film shape by using a stencil printing method.

14. The method of manufacturing a dielectric film according to claim 1, wherein
the dielectric film is a dielectric film for a piezoelectric body of an ultrasonic sensor, and
the forming step includes a step of forming the film-like compact on a surface of an inspection object to be inspected by the ultrasonic sensor and sintering the film-like compact on the surface of the inspection object.

15. The method of manufacturing a dielectric film according to claim 1, wherein
in the forming step, the film-like compact is formed on a release sheet.

16. The method of manufacturing a dielectric film according to claim 15, wherein
the dielectric film is a dielectric film for a piezoelectric body of an ultrasonic sensor, and
the method further includes the steps of:
attaching the film-like compact that has been peeled off from the release sheet to a surface of an inspection object to be inspected by the ultrasonic sensor; and
sintering the film-like compact on the surface of the inspection object.
